(19) United States
(12) Patent Application Publication
(10) Pub. No.: US 2010/0037938 A1
(43) Pub. Date: Feb. 18, 2010

(54) POWER SOURCE

(76) Inventor: Gerald Peter Jackson, West Chicago, IL (US)

Correspondence Address: PETER K. TRZYNA, ESQ., P O BOX 7131, CHICAGO, IL, 60680, US

(21) Appl. No.: 12/375,176

(22) PCT Filed: Jul. 26, 2007
(86) PCT No.: PCT/US07/74446

§ 371 Date: Sep. 15, 2009

Related U.S. Application Data
(63) Continuation of application No. 11/828,311, filed on Jul. 25, 2007.
(60) Provisional application No. 60/833,335, filed on Jul. 26, 2006.
(60) Provisional application No. 60/900,866, filed on Feb. 12, 2007.

(51) Int. Cl. H01L 31/00

(52) U.S. Cl. 136/252

(57) ABSTRACT

Process, machine, manufacture, composition of matter, and improvements thereto, with particular regard to generating electrical power. Representatively, the method can include: increasing temperature of a surface to produce radiation, a portion of the radiation having an infrared wavelength and a portion of the radiation having a wavelength shorter than the infrared wavelength; reflecting the infrared wavelength portion of the radiation emanating from said surface Surface back toward said surface; and collecting the shorter wavelength portion of the radiation in a photovoltaic device to generate electrical power.

### I. CONTINUITY STATEMENT

This patent application is a continuation-in-part, claiming priority from, and incorporating by reference, the provisional patent applications “Power Source Based on Tuned Photovoltaic Conversion,” Ser. No. 60/833,335, filed Jul. 26, 2006; “Chemical Conversion Based on Photovoltaic Conversion”, Ser No. 60/900,866, filed Feb. 12, 2007; and “Power Source,” Ser. No. 11/828,311, filed Jul. 25, 2007.

### II. BACKGROUND

### A. Technical Field

Process, machine, manufacture, composition of matter, and improvements thereto, with particular regard to radioactive decay of isotopes, fission of nuclear materials, fusion, chemical reactions, and the like in generating electrical power.

### III. BRIEF DESCRIPTION OF THE DRAWINGS

FIG. 1 is an energy flow diagram.

FIG. 2 is a list of some heat sources.

FIG. 3 is a list of some surface blackbody radiation considerations.

FIG. 4 is an illustration of an embodiment of the apparatus in which the heat source is the nuclear decay of a radioisotope.

FIG. 5 is an illustration of the shape of the ZrO₂ supports for temperature profile calculations.

FIG. 6 is a graph of calculated temperature profile across the ZrO₂ supports.

FIG. 7 is a graph of measured surface emissivity of tungsten as a function of wavelength.

FIG. 8 is a graph of reflectivity vs. wavelength for a protected gold substrate hot mirror.

FIG. 9A is a graph of photovoltaic conversion efficiency of some technologies as a function of wavelength in microns.

FIG. 9B is a graph of photovoltaic conversion efficiency of some technologies as a function of wavelength in nanometers.

FIG. 10 is a graph of calculated spectral emissions, reflectivity, and transmission of light.

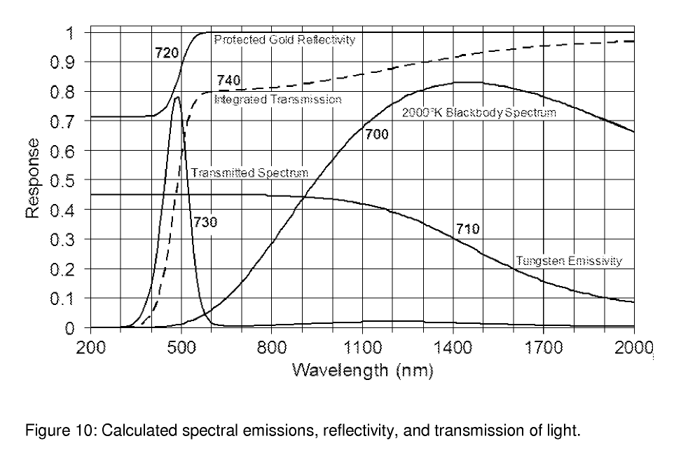

FIG. 11 is an illustration of a cylinder cross-section demonstrating the flexibility of the radioisotope power supply architecture.

FIG. 12 is an illustration of some applications for the method and apparatus.

### V. MODES

Turn now to the accompanying drawings, which illustrate embodiments in detail intended to illustrate and exemplify in a teaching and prophetic manner, rather than limit—much like teaching mathematical addition by examples rather than by an explicit compendium of all addition possibilities.

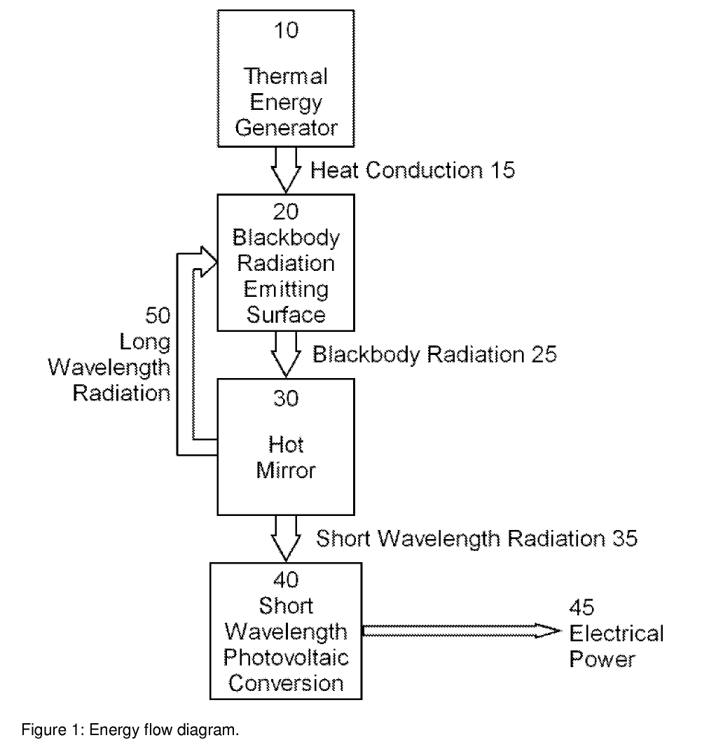

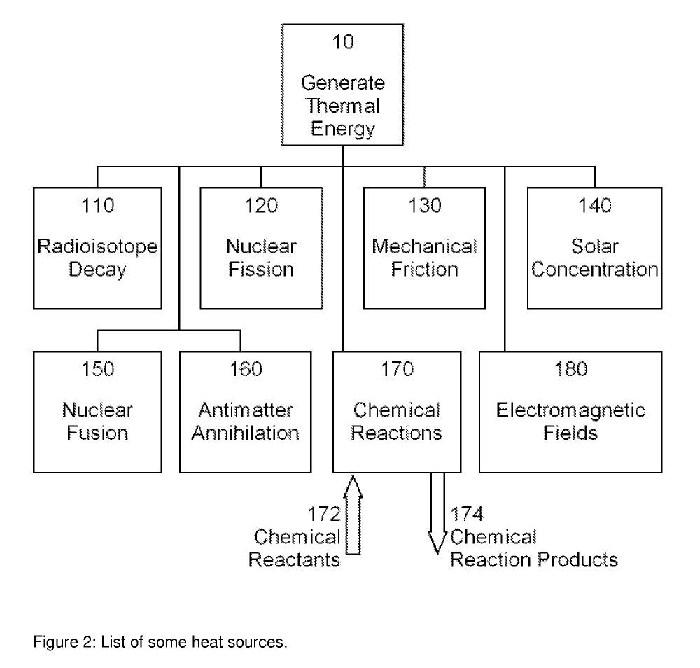

FIG. 1 shows a general energy flow diagram for an embodiment. Consider a thermal energy generator 10. As seen in FIG. 2, a method of generating thermal energy 10 can include radioisotope decay 110, nuclear fission 120, mechanical friction 130, solar energy concentration 140, nuclear fusion 150, antimatter annihilation 160, chemical reactions 170, and the interaction of electromagnetic fields 180 with matter, such as a surface emitting blackbody radiation 20. Chemical reactions may involve the introduction of chemical reactants 172, and may result in the emission of chemical reaction products 174.

This thermal energy is conducted via convection, radiation, or physical coupling to a surface 20 that radiates this thermal energy in the form of blackbody radiation 25. Because the blackbody radiation spectrum is so broad, prior technologies at harnessing this energy for power production were limited in acceptance and hence operated at reduced efficiency. By reflecting the long wavelength 50 portion of this radiation back toward said emitting surface 20 and transmitting only the upper short wavelength 35 edge of the blackbody radiation spectrum, only a narrow band 730 in the electromagnetic spectrum is transmitted for harvesting via photovoltaic 380 conversion 40 into electrical power 45. A device capable of reflecting long wavelengths and transmitting short wavelengths is called a hot mirror 30.

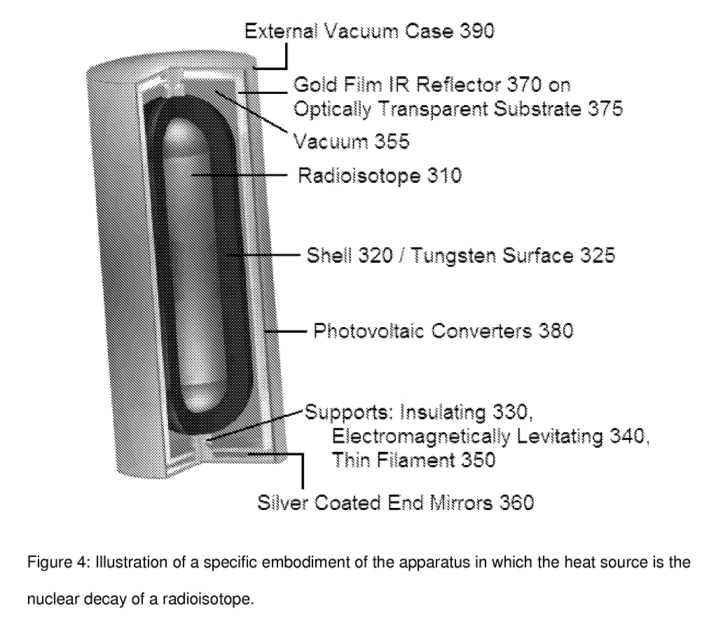

In a particular embodiment particularly suitable as a teaching example, consider a system architecture in which radioisotopic nuclear decay energy 110 is completely or essentially encapsulated within a tungsten shell 320, and converting, with high efficiency, the energy from the decay into thermal energy 15. See FIG. 4. The tungsten shell 320 can be in a vacuum 355 or essentially a vacuum. In one configuration, there can be one or more supports (embodiments including supports composed of thermally insulating materials 330, magnets or coils 340 for electromagnetic levitation, or thin wires or filaments 360) so as to allow almost no heat to leak. Therefore, the temperature of the surface 325 of the tungsten shell increases until blackbody radiation photons 25 are the dominant source of heat dissipation.

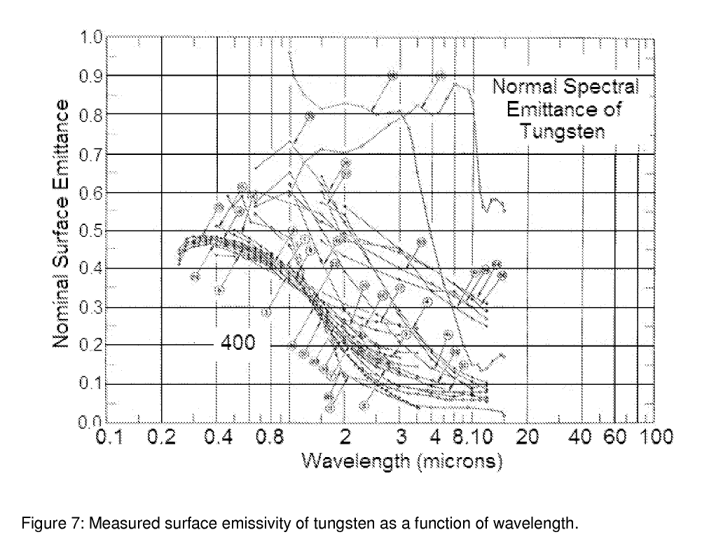

As seen in FIG. 7, tungsten has the crucial property that its emissivity 400 is very low (˜0.05) at infrared wavelengths and almost 0.5 at visible wavelengths 730. In a particular embodiment, the tungsten shell 320 can be surrounded with highly efficient infrared reflectors 370 (e.g., hot mirrors with each comprised of a thin gold film 370 on a transparent substrate 375, which become transparent between 600 and 900 nm). As a result, the temperature of the tungsten shell 320 increases until the visible photon power transmitted 730 through the hot mirrors 370 essentially equals the heat generation power of the radioisotope 310.

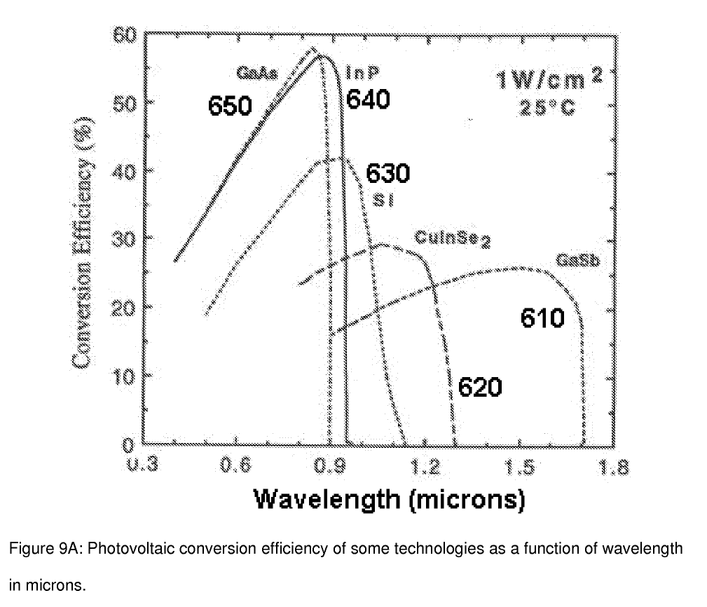

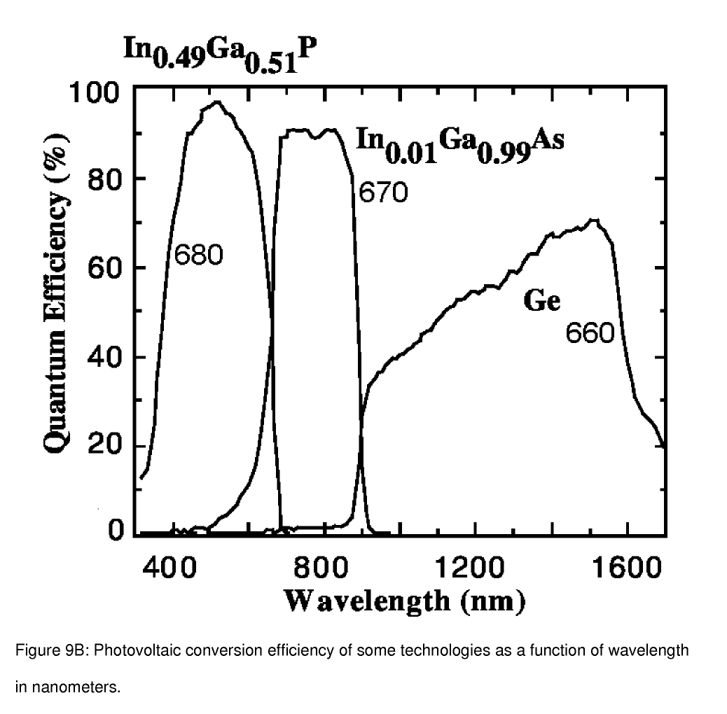

As seen in FIG. 9B, in this filtered portion of the blackbody radiation corresponding to a tungsten surface temperature of 1700° C. 700, GaInP photocells have an average power conversion efficiency 680 approaching 100%. Hence, the architecture is such that the transmitted photon power spectrum 730 is tuned to the peak response of a high-efficiency power conversion device 380. This can be a highly precise tuning, wherein the visible photon power transmitted 730 through the hot mirrors 370 just equals the heat generation power of the radioisotope 310.

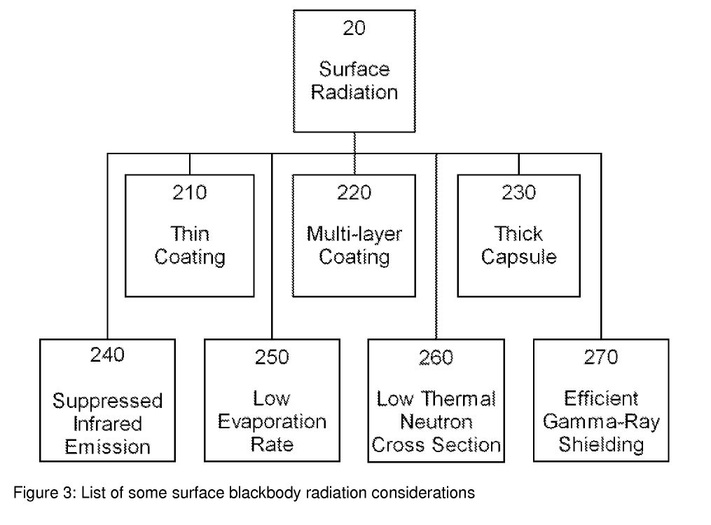

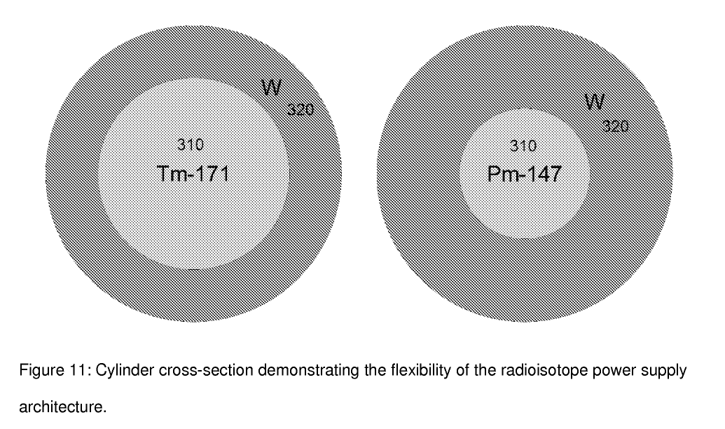

Embodiments that follow this example can be directed to any isotope according to its power density and radiation leakage properties. Low leakage rates can equate to low possibility of radiation induced degradation of any active component of the system. As seen in FIG. 11, the power density of various radioisotopes 310 can be traded off against the amount of tungsten shielding 320 of decay radiation in order to yield the same package size. As shown in FIG. 3, the emission of blackbody radiation at a surface 20 can be implemented by a thin coating 210 on an otherwise thick shell, a multi-layer coating 220, or a thick shell 230 that is uncoated. Choices of shell 320 and coating 325 materials are driven by considerations such as suppression of infrared radiation 240, low evaporation/sublimation rates 250, low thermal neutron cross section 260, and efficient gamma-ray shielding 270.

Consider the following variations on the theme for such a power source architecture and accompanying isotope synthesis:

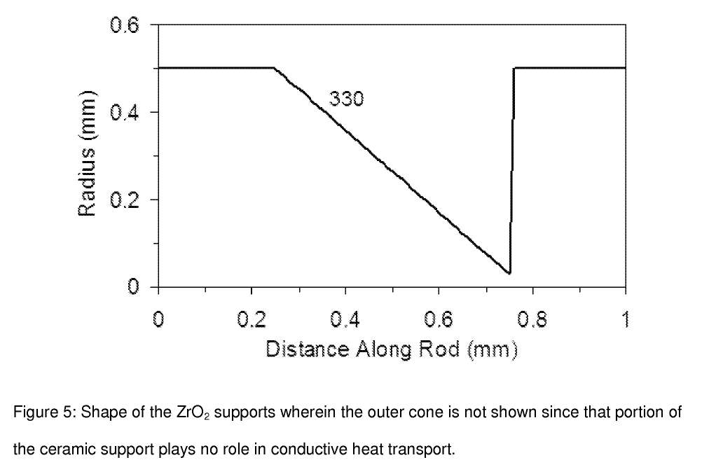

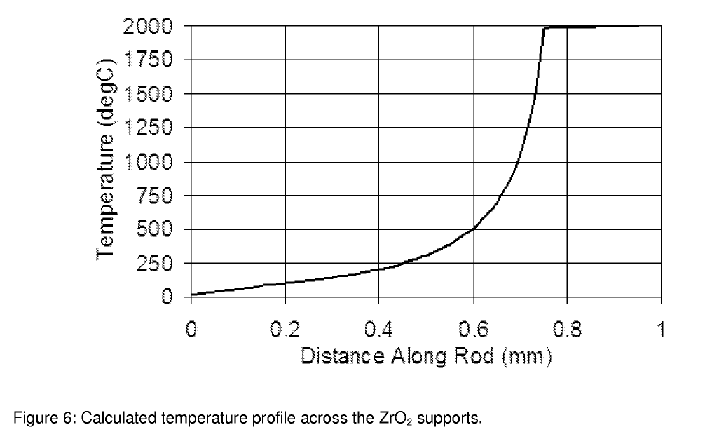

1) Electrical power conversion 40 efficiencies can be in the range of at least 10%, preferably in the range of 10% to 30%, and more preferably in the range of more than 30% to achieve power densities. However, in this particular example, the end supports do transmit some thermal power (see FIGS. 5 and 6), plus the hot mirror system has some loss, so the overall system efficiency can be limited below the GaInP efficiency of 90%.

2) In the case of radioisotopes 310 as the source of thermal energy, radiation leakage at 1-foot can be in the range of 100 to 500 mrem/year, preferably in the range of 50 to 100 mrem/year, and more preferably in the range of less than 50 mrem/year.

3) In the case of radioisotopes 310 as the source of thermal energy, sealed source geometry that shields surrounding materials and electronics to radiation levels at or below normal background. The volume of isotope and the thickness of the tungsten shield can be selected in amounts traded against each other to accommodate a broad range of suitable isotopes. For example, a 35 milliWatt electric power source can fit into a 1 cc volume wherein the thickness of the tungsten shell is approximately 1.2 mm. This kind of configuring of the encapsulation of the source of radiation prevents radiation induced degradation of active components.

4) Power conversion can be adapted to output continuous electrical power 45, e.g., into fixed electrical impedance, regardless of the age of the isotope 310 (i.e., with respect to its half-life).

5) Passive titanium vacuum gettering can be used behind the end mirrors 360 to preserve the thermal insulation vacuum 355 around the tungsten shell 320. Specific assembly of this architecture in a vacuum 355 system can allow the radiative heat from the tungsten shell 320 to vacuum process the components before sealing the outer casing 390.

6) Embodiments can be configured for a low thermal signature. Due to total efficiencies in the ranges of 10% to 50%, preferably greater than 50% or an embodiment with an efficiency of approximately 33%, a 35 mWₑ (milliWatt electric) power source can have a surface heat dissipation rate of only 0.1 Watt. At this power level, an initial shape of a 1 cc unit is similar to a 0.75″ section of a standard pencil. Thus such an embodiment can be about twice as long, and about three times larger in surface area, of a standard 1 Watt resistor, and therefore remain close to room temperature.

Heat leak calculations of the end supports are shown in FIGS. 5 and 6. Note that in FIG. 5 an outer cone is not shown because that portion of a ceramic support plays essentially no role in conductive heat transport. In one embodiment, these supports can be composed of ZrO₂ 330. A cone-within-a-cone geometry embodiment can simultaneously restrict heat flow and provide rigid support of the radioisotope 310 and tungsten shell 320. In another embodiment, there can be 0.5 mil diameter tungsten wires 350 on each end. In yet another embodiment, magnets, electrodes, and coils 340 can be used to magnetically levitate the shell 320 and prevent contact with the hot mirror 370. Table 1 contains a summary of estimated the power and efficiency factors showing high overall efficiency.

TABLE 1
Calculation of allowable heat leak through the end supports
and via residual infrared radiation leakage.

| | |
|---|---|
| Radioisotope Power (mWₜₕ) | 105 |
| Electric Conversion Efficiency | 50% |
| Power for Users (mWₑ) | 35 |
| Power Radiated to Converters (mWₜₕ) | 70 |
| Power Allocated for Heat Leak (mWₜₕ) | 35 |
| Net Conversion Efficiency | 33% |

Tungsten has an emissivity that is very low (˜0.05) at infrared wavelengths and almost 0.5 at visible wavelengths. Depending on surface roughness, a variety of specific emissivity curves 400 are summarized in FIG. 7. Note that in this figure the vertical emissivity scale is linear, ranging from zero to unity, and the horizontal logarithmic wavelength scale starts at 0.1 microns and ending at 100 microns. The dominant transition is at 1 micron. If, as per one embodiment, chemical vapor deposition (CVD) is used to deposit this tungsten layer 210 around the radioisotope 310, there can be very good control over surface conditions.

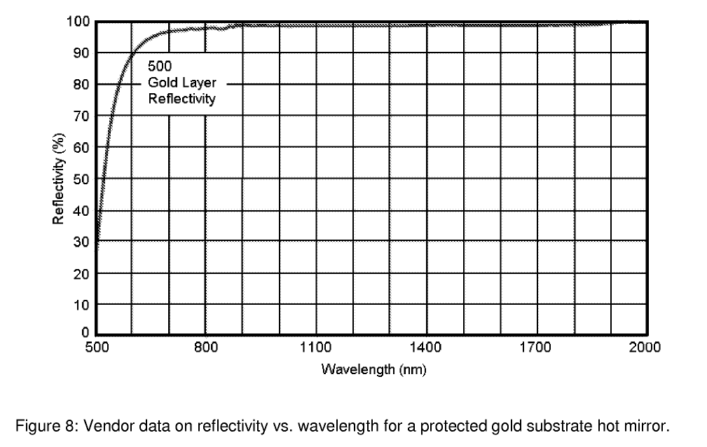

Surrounding the tungsten shell surface 325 can be highly efficient infrared reflectors (hot mirrors) composed of a thin gold film 370 on a transparent substrate 375, which can suddenly become transparent between 600 and 900 nm. The temperature of the tungsten shell 320 increases until the visible photon power transmitted 730 through the hot mirrors 30 essentially just equals the heat generation power 10 of the radioisotope 310. FIG. 8 illustrates reflectivity 500 for a single layer.

In such an embodiment, an architecture can created in which the photon power spectrum is precisely tuned to the peak response of a high-efficiency power conversion device 40. A summary of the spectral efficiencies of a number of photovoltaic technologies are illustrated in FIGS. 9A and 9B. Note that GaInP 680 represents a valid embodiment, while technologies such as GaSb 610, CuInSe 620, Si 630, InP 640, GaAs 650, Ge 660, and GaAsIn 670 all have sensitivity ranges at wavelengths that are too long 50.

Representing still another embodiment, by using an alternative hot mirror 30 technology that transmits light starting at either 1.2 or 1.7 microns, significantly lower tungsten surface 325 temperatures can be used. The result is less heat leak out the end supports 330. Preliminary calculations suggest that the overall system efficiency would drop from about 33% to approximately 20%.

Representing another embodiment, consider a manner of adjusting an architecture for embodiments herein, represented by an output power 45 of 35 mWₑ deposited into a 50 Ω load corresponds to a voltage of 1.3 V and a current of 38 mA. Because the output power of radioisotopes 310 decay with time, the initial power level of radioisotope power sources will be much higher, and decay down to 35 mWₑ after a few half-lives. By employing pairs of tap that the user can electronically short or open via semiconductor gates, progressively more of the photovoltaic 380 surface area can be brought online while the isotope activity decays. These latter sections of surface area are wired in compensating parallel-series configurations to yield an overall net output impedance of roughly 50 Ω.While not a continuous load adjustment, several surface area steps can be implemented that approximate a constant 50 Ω output impedance.

This power conditioning solution consumes negligible additional mass and essentially zero power source volume. It also can provide a means for direct control over power delivery. For example, assume higher amounts of peak power are to be utilized periodically, so as to benefit from the control. Alternatively, one can set the current vs voltage I-V operating point of the photovoltaic cells 380 to maximum efficiency at the end of operational life of the power source, and then run off-optimum at the beginning of the half-life decay curve of the radioisotope 310.

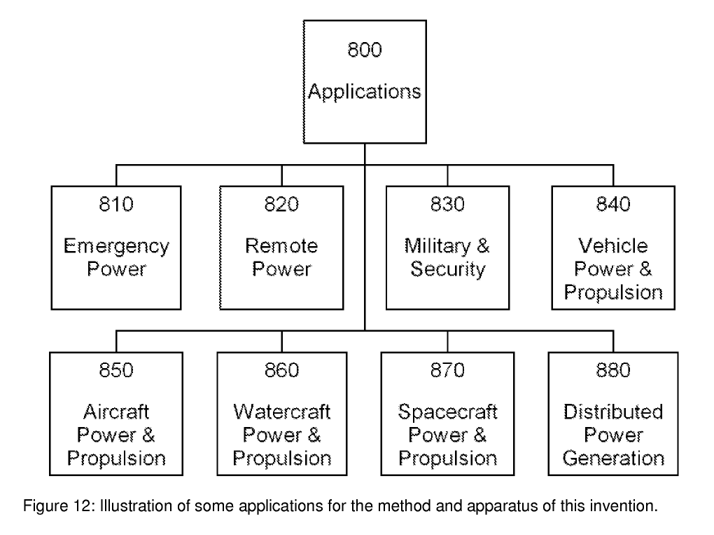

As seen in FIG. 12, there are many applications 800 for the methods and apparatus. These applications include emergency power 810, remote power 820, military and security 830, vehicle power and propulsion 840, aircraft power and propulsion 850, watercraft power and propulsion 860, spacecraft power and propulsion 870, and grid electrical power generation 870. One application of particular interest is the use of embodiments herein for powering electric automobiles 840.

Embodiments of emergency power applications 810 include recharging vehicle batteries that have run down, preventing the owner from starting the vehicle. It also includes backup power in the case of a terrorist attack on the electrical grid infrastructure.

Embodiments of remote power applications 820 include camp site and cabin power, power at scientific field locations, and pumping stations for field irrigation. Basically, any temporary power requirement not conveniently connected to the electrical grid qualifies under this application 800 category.

Embodiments of military and security applications 830 include powering weapon systems, recharging batteries carried by soldiers for range finders and radios, powering listening posts and other remote intelligence gathering equipment, powering portable radiation monitoring stations, and providing robust power for underwater operations such a welders employed by divers, powering smart mines, and propelling torpedoes. Embodiments include applications requiring operations in extreme temperatures, pressures, and oxygen deficiency environments that are beyond the capabilities of current power generation and storage systems.

Embodiments of vehicle power and propulsion applications 840 include automobile power, either for all or a portion of the power, used to propel the automobile. Further embodiments include vehicles such as trucks, boring machines, and locomotives. Further embodiments include vehicle power, such as for hydraulic system pumps and energy recovery from high-efficiency regenerative brakes employing the technology of embodiments herein.

Embodiments of aircraft power and propulsion applications 850 include direct power for an electric motor driving a propeller. Further embodiments include aircraft power for navigation, communications, and weapon systems.

Embodiments of watercraft power and propulsion applications 860 include propulsive power for boats, ships, hovercrafts, and jet skis. Further embodiments include onboard power for equipment such as fish finders, bottom finders, sonar systems, and weather radar.

Embodiments of spacecraft power and propulsion applications 870 include electrical power for ion engines. Further embodiments include scientific instrument, navigation, temperature control, and communication power,

Embodiments of grid electrical power generation applications 880 include energy storage during off-peak demand times by regenerating embodiments based on chemical reactions. In this embodiment, chemical reaction products would be reformed back into their original chemical reactant form. Another embodiment includes electrical power generation during peak demand times by converting solar energy.

Consider now a broader application of the foregoing teaching, with regard to conversion of a source of energy into electrical power. The teachings herein facilitate an apparatus, method of making the apparatus, and method of using the apparatus. The apparatus, depending on preferred implementation, be adapted to generate electrical power by conversion from a source of energy, with no moving parts, and with energy conversion efficiency greater than 20%, greater than 30%, greater than 40%, greater than 50%, greater than 60%, and more preferably greater than 80%. Inefficient power systems have heretofore been a technical problem, and the embodiments herein and thereby offer a technical solution thereto.

Note that the foregoing is a prophetic teaching and although only a few exemplary embodiments have been described in detail herein, those skilled in the art will readily appreciate from this teaching that many modifications are possible, based on the exemplary embodiments and without materially departing from the novel teachings and advantages herein. Accordingly, all such modifications are intended to be included within the scope of the defined by claims. In the claims, means-plus-function claims are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment fastening wooden parts, a nail and a screw may be equivalent structures.

1. A method of generating electrical power, the method comprising:
increasing temperature of a surface to produce radiation, a portion of the radiation having an infrared wavelength and a portion of the radiation having a wavelength shorter than the infrared wavelength;
reflecting the infrared wavelength portion of the radiation emanating from said surface back toward said surface; and
collecting the shorter wavelength portion of the radiation in a photovoltaic device to generate electrical power.

2.-104. (canceled)
